(19) United States
(12) Patent Application Publication
(10) Pub. No.: US 2015/0221388 A1
(43) Pub. Date: Aug. 6, 2015

(54) ABRIDGED ERASE VERIFY METHOD FOR FLASH MEMORY

(71) Applicant: Integrated Silicon Solution, Inc., Milpitas, CA (US)

(72) Inventors: Jong Sang Lee, San Jose, CA (US); Kyoung Chon Jin, San Ramon, CA (US)

(73) Assignee: Integrated Silicon Solution, Inc., Milpitas, CA (US)

(21) Appl. No.: 14/174,764

(22) Filed: Feb. 6, 2014

(51) Int. Cl. G11C 16/34; G11C 16/08; G11C 16/16

(52) U.S. Cl. CPC G11C 16/3445; G11C 16/16; G11C 16/08

(57) ABSTRACT

A non-volatile memory device includes a control circuit configured to perform a block erase operation including a block erase cycle and an erase verify cycle on a block of memory cells. The control circuit is configured to perform the erase verify cycle by storing a last verify address for each sector of the block of memory cells, verifying each memory cell in a sector starting from the last verify address for the sector until a memory cell has failed erase verification in that sector, storing the memory cell address of the failed memory cell as the last verify address for that sector, skipping the erase verification for the remaining memory cells in that sector, and continuing the erase verify cycle at a last verify address for the next sector.

### BACKGROUND OF THE INVENTION

Non-volatile memory (NVM) is a memory device that retains content stored therein even when power is removed. EEPROM and flash memory are two commonly used non-volatile memory devices. In particular, flash memory has become widely used in electronic devices, especially portable electronic devices, because of its ability to provide data storage at low power levels. Modern day flash memory devices are typically implemented using a floating gate MOS transistor device as the memory cells. A floating gate MOS transistor device includes a floating gate that is formed between a control gate and the channel region (the substrate) of the MOS device and at least partially vertically aligned with the control gate. Charge storage on the floating gate determines the stored data state (“0” or “1”) of the memory cell.

In a non-volatile memory cell implemented using a floating gate MOS device, programming of the memory cell, or writing data to the memory cell, is accomplished by transferring charge carriers from the semiconductor substrate (the source or the drain) to the floating gate by tunneling through the thin gate oxide layer. Typically, a block or a sector of non-volatile memory cells is first erased by applying bias conditions to remove the charges stored on the floating gate. Then, the non-volatile memory cells can be written or programmed, usually one byte or word at a time, by applying the bias conditions opposite to the erase operation. Erase and programming operation of non-volatile memory devices require a relatively large voltage and current and erase and programming cycles can be slow.

Flash memory cells can be programmed individually but are usually erased as a block or a sector. Each erase operation includes the application of an erase pulse followed by an erase verify operation to ensure that all memory cells are indeed erased. If some of the memory cells are not erased, then another erase pulse is applied and the process repeats until all memory cells are erased. The erase and verify process can be very long.

### BRIEF DESCRIPTION OF THE DRAWINGS

Various embodiments of the invention are disclosed in the following detailed description and the accompanying drawings.

FIG. 1 is a block diagram of a non-volatile memory (NVM) device in one exemplary embodiment.

FIG. 2 is a cross-sectional view of a flash memory cell implemented using a floating gate MOS transistor device in some examples of the present invention.

FIG. 3 illustrates a flash memory array in one example configuration.

FIG. 4 is a flowchart illustrating an abridged erase verify method for block erase operation in a flash memory device which can be implemented in the flash memory device of FIG. 1 in embodiments of the present invention.

FIG. 5 is a flowchart illustrating a block erase method in a flash memory device in embodiments of the present invention.

FIG. 6, which includes FIGS. 6(a) and 6(b), illustrates the erase verify process using the abridged erase verify method for block erase operation in some examples of the present invention.

FIG. 7 is a flowchart illustrating an abridged erase verify method in a flash memory device in alternate embodiments of the present invention.

### DETAILED DESCRIPTION

The invention can be implemented in numerous ways, including as a process; an apparatus; a system; and/or a composition of matter. In this specification, these implementations, or any other form that the invention may take, may be referred to as techniques. In general, the order of the steps of disclosed processes may be altered within the scope of the invention.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

In embodiments of the present invention, a method for performing erase verify for block erase operation in a flash memory device reduces erase verify time by using stored failed addresses for each sector in the block during a previous erase verify cycle. Subsequent erase verify cycle begins erase verification from the stored failed address of each sector, instead of from the beginning of each sector. Accordingly, the erase verify time for block erase operation becomes the time it takes to verify each memory cells in the block without substantial repetition. The abridged erase verify method of the present invention can realize a significant reduction in erase verify time as compared to conventional methods.

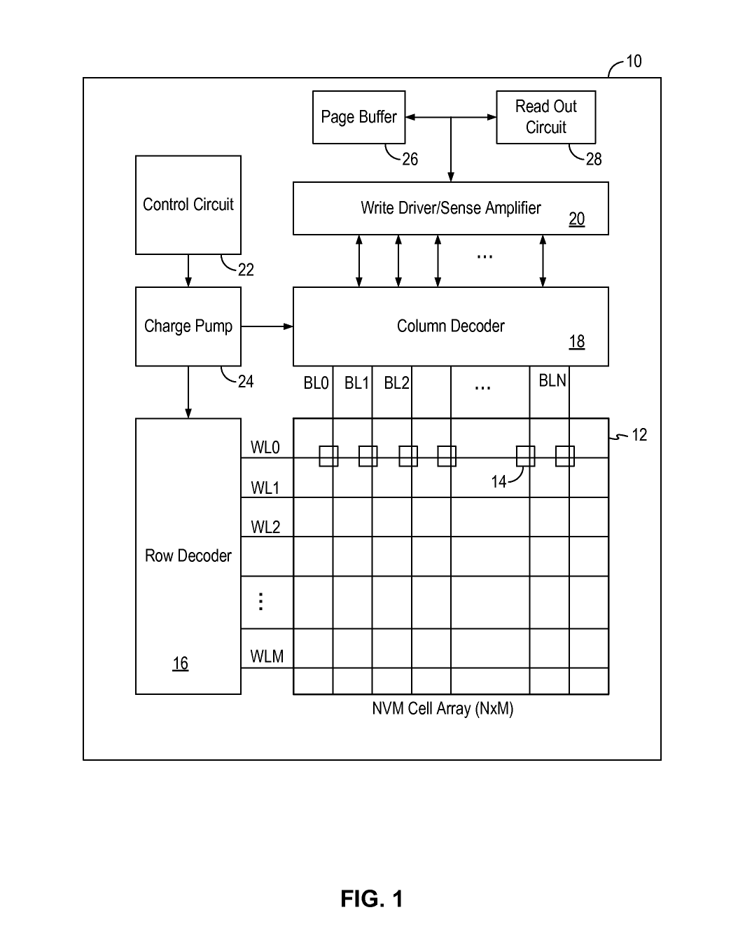

FIG. 1 is a block diagram of a non-volatile memory (NVM) device in one exemplary embodiment. FIG. 1 is illustrative only and the NVM device may include additional components not shown in FIG. 1. Referring to FIG. 1, the NVM device 10 includes a two-dimensional array 12 of non-volatile memory cells 14. In the present embodiment, NVM device 10 is implemented as a flash memory device and non-volatile memory cells 14 are implemented as flash memory cells. In other embodiments, the NVM device 10 may be implemented as other types of non-volatile memory device.

In embodiments of the present invention, flash memory cells 14 may be configured as a NAND flash memory array or a NOR flash memory array. The cell array 12 is addressed by a row decoder 16 and a column decoder 18 to allow a control circuit 22 to selectively access the memory cells 14 for read, program (write) and erase operations. In particular, the flash memory cells 14 in the array 12 are accessed by word lines WL0 to WLM and bit lines BL0 and BLN. The row decoder 14 selectively activates a word line from WL0 to WLM and the column decoder selectively activates a bit line from BL0 to BLN to allow a memory cell 14 at the intersection of the selected word line and selected bit line to be accessed. A charge pump 24 is used to provide the appropriate voltage and current required for the erase and write operations of the NVM cell array 12. A write driver and sense amplifier circuit 20 is used to write data to or read data from the NVM cell array 12. In practice, the write driver and sense amplifier circuit 20 includes a bank of write drivers and sense amplifiers, one set of write driver and sense amplifier for each input/output (I/O) of the flash memory device. Each set of write driver and sense amplifier is coupled to a block of memory cells 14 in the cell array 12. The write driver and sense amplifier circuit 20 may be coupled to a page buffer 26 to receive program data to be written into the cell array 12 and may be further coupled to a read out circuit 28 to provide data read out from the cell array 12 to external circuits. The memory architecture shown in FIG. 1 is illustrative only and it will be appreciated that the structure and methods described herein may be utilized in other memory architectures.

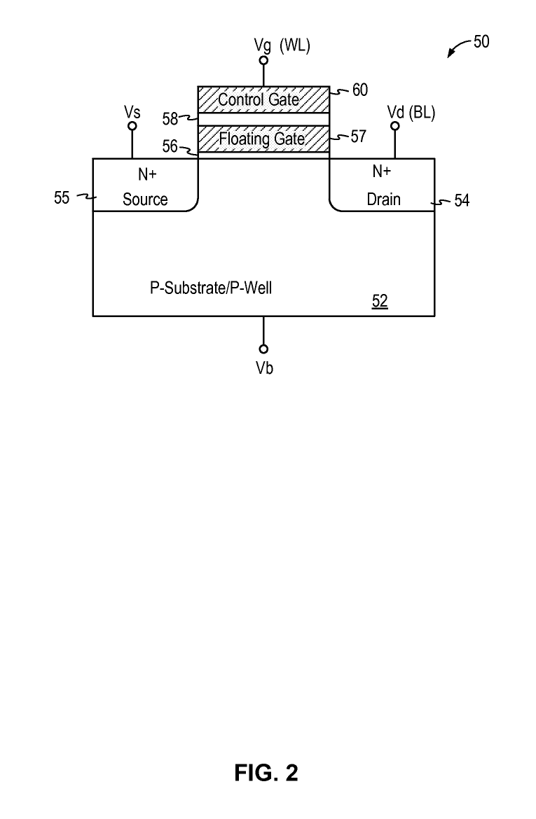

In the present embodiment, flash memory cells 14 are implemented using a floating gate MOS transistor device, as shown in FIG. 2. Referring to FIG. 2, a floating gate MOS transistor device 50 includes a source region 55, a drain region 54, a control gate 60 and a floating gate 57. The source and drain regions are formed in a semiconductor layer 52 with the channel region disposed in between the source and the drain regions. In some examples, the semiconductor layer 52 can be a well region or a semiconductor substrate. In the present example, the floating gate MOS transistor device 50 is formed as an N-type device and the semiconductor layer 52 is a P-type well region with the source and drain regions being heavily doped N+ regions formed in the P-well region 52. The floating gate 57 and the control gate 60 are vertically disposed above the channel region and at least partially overlapped. The floating gate 57 is electrically isolated from the P-type well region 52 by a thin gate oxide layer 56 (also referred to as the “tunnel oxide layer”) and is electrically isolated from the control gate 60 by another dielectric layer 58 which can be a dielectric film or a stack of different dielectric films. The control gate 60 of the floating gate MOS transistor device 50 is coupled to the word line of the cell array while the drain region is coupled to the bit line of the cell array. In a NOR flash memory, the source regions of the floating gate MOS transistor devices are connected to a shared source line which is typically connected to the ground potential.

The operation of the flash memory device 10 and the floating gate flash memory cell 50 is well known and will be described in brief. In the present example, the flash memory cell has a logical state of “1” when the cell is erased and a logical state of “0” when the cell is programmed. It is understood that flash memory cells may be constructed to operate in the opposite logical states.

First, programming or writing data to the flash memory cell is performed by transferring charge carriers from the semiconductor layer 52 to the floating gate 57 by tunneling through the thin gate oxide layer 56. For example, an elevated gate voltage (e.g. Vg=12V) is applied to the control gate to turn on the channel and electrons can flow from the source to the drain. The P-well region 52 is typically grounded. An elevated drain voltage (e.g. Vd=5V) is applied to the drain region 54 relative to the source region 55 to generate electrons with sufficiently high energy (“hot electrons”) so that hot electronic injection occurs and hot electrons jump through the thin gate oxide layer 56 onto the floating gate 57. When the biasing voltages are removed, the charges are trapped on the floating gate 57 and the memory cell is programmed to a logical state of 0.

Second, erasing the flash memory cell is performed by transferring charge carriers from the floating gate to the semiconductor layer 52 (or P-well 52) by quantum tunneling or Fowler-Nordheim tunneling. The erase operation can be carried out using source erase operation or channel erase. To perform source erase, an elevated negative voltage (e.g. Vg=−10V) is applied to the control gate 60 and the substrate is at ground. A positive voltage (e.g. Vd=6V) is applied to the source region 55 with the drain region 54 being grounded or floating. Electrons are pull off the floating gate into the source through quantum tunneling. When the floating gate is left with no charge carriers, the memory cell has a logical state of 1. To perform channel erase, an elevated negative voltage (e.g. Vg=−10V) is applied to the control gate 60 and a positive voltage (e.g. Vb=5V) is applied to the semiconductor layer or P-well 52. The source region 55 and the drain region 54 are left floating. Electrons are pull off the floating gate into the substrate through quantum tunneling. When the floating gate is left with no charge carriers, the memory cell has a logical state of 1.

Flash memory cells can be programmed individually but are usually erased as a block or a sector. Each erase operation includes the application of an erase pulse followed by an erase verify cycle to ensure that all memory cells are indeed erased. If some of the memory cells are not erased, then another erase pulse is applied and the process repeats until all memory cells are erased. In both source erase and channel erase operations, the magnitude and the duration of the voltage bias can vary and are selected to ensure that all memory cells in a sector a block are erased. In most cases, the flash memory device is erased using a repeated erase-verify operation when the memory cells are verified to be erased after an erase cycle and the erase cycle is repeated if not all memory cells are erased.

Finally, a flash memory cell is read by applying a gate voltage that is an intermediate threshold voltage of an erased memory cell and a programmed memory cell. When a flash memory cell is erased, the floating gate carries no charge and the memory cell transistor can be turned on by the application of a first threshold voltage. However, when the flash memory cell is programmed, the negative charge on the floating gate screens the electric field from the control gate, the memory cell transistor thus requires a second threshold voltage higher than the first threshold voltage to turn on. Thus, to read a flash memory cell, a gate voltage between the first and second threshold voltages are applied to the control gate and a drain voltage, smaller than the gate voltage, is applied to the drain. If a current is measured at the drain terminal, then the memory cell is not programmed and has a logical state of 1. If no current is measured at the drain terminal, then the memory cell is programmed and has a logical state of 0.

To access a flash memory cell in the cell array 12, an input address is provided to flash memory device 10. The input address is divided into a row address which is coupled to the row decoder 16 and a column address which is coupled to the column decoder 18. Row decoder decodes the row address and activates one word line out of word lines WL0 to WLM and column decoder decodes the column address and activates one bit line out of bit lines BL0 to BLN. In this manner, the memory cell associated with the activated word line and the activated bit line is made available for either read, write or erase operation. In practice, the flash memory device activates the memory cells associated with all of the I/Os of the memory device. For example, the memory cells associated with one byte of data or eight I/Os, may be activated for access based on the input address. More specifically, the conventional flash memory device activates one bit line for each associated write driver/sense amplifier in the flash memory device. In the following description, the operation of the flash memory device will be described with reference to a single write driver/sense amplifier or a single I/O. It is understood that the flash memory device includes a bank of write drivers and sense amplifiers for a set of I/Os, such as a byte of data.

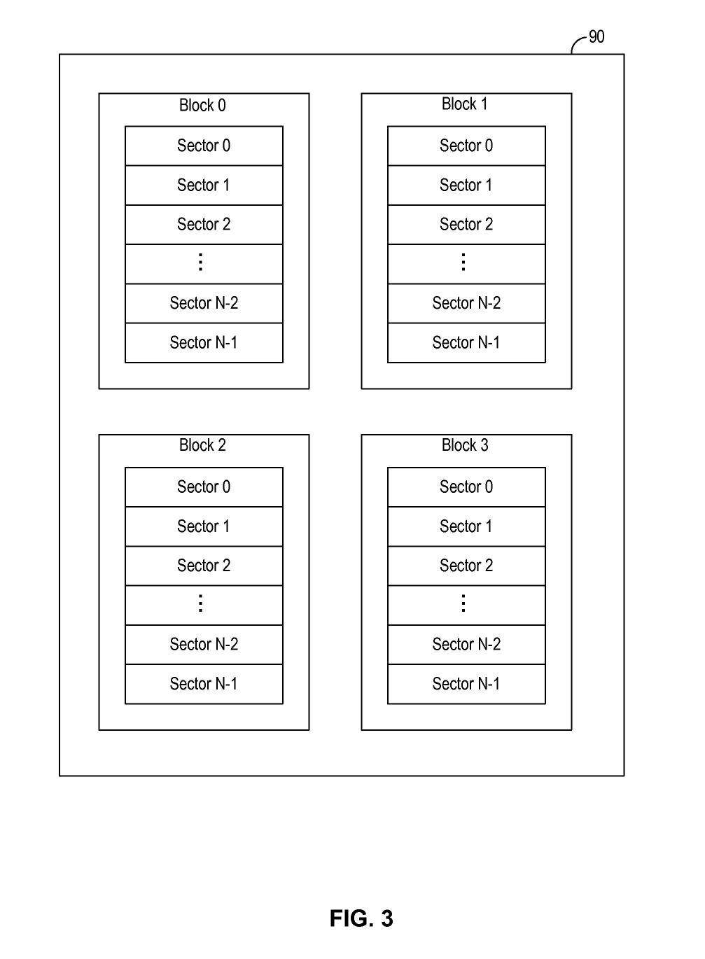

A flash memory array is typically arranged in multiple blocks with each block containing multiple sectors. FIG. 3 illustrates a flash memory array in one example configuration. Referring to FIG. 3, a flash memory array 90 may be organized into M blocks (e.g. Block 0 to Block 3) with each block further organized into N sectors (Sector 0 to Sector N−1). In some embodiments, each block of memory cells is formed in a separate P-well. In one example, a block of memory may contain 32 kB with each sector containing 4 kB of memory cells. The flash memory erase operation can be performed using block erase or sector erase. In a block erase operation, each block is erased individually. In a sector erase operation, each sector in a block is erased individually. The memory cells in a selected block or a selected sector are erased all together. After an erase cycle, an erase verify cycle is performed to ensure that all memory cells are indeed erased. If one or more of the memory cells are not erased, then another erase pulse, with the same or different voltage magnitude or time duration, is applied and the memory cells are verified again after the erase pulse. The erase and erase verify process repeat until all the memory cells in the selected block or selected sector are verified to be erased.

In the present description, the term “erase operation” refers to performing one or more erase cycles and one or more erase verify cycles to selected memory cells, usually a block or a sector. Furthermore, the term “erase cycle” refers to the application of an erase pulse to erase the selected memory cells (block or sector). Finally, the term “erase verify cycle” or “erase verification cycle” refers to performing verification of the erase status of the erased memory cells through one pass of the erased memory cells (block or sector). Accordingly, in the present description, a “block erase operation” refers to performing one or more “block erase cycles” and one or more “erase verify cycles” to a block of memory cells until all the memory cells in the block have been verified as being erased or in an erase state. Typically, an erase verify cycle follows each erase cycle. In embodiments of the present invention, an erase verify cycle can be performed before the first erase cycle, as will be described in more detail below.

The conventional erase verification cycle for a block erase operation starts at the first memory cell address in each sector for each erase verification cycle. Thus, at each erase verification cycle, the verify process begins with the first memory cell in the first sector and goes through all the memory cells in that sector. Then, the verify process moves onto the next sector where the verify process begins with the first memory cell in the next sector. At each erase verify cycle, the verify process verifies each and every memory cell in each sector of the block. When an erase failure is detected, another erase pulse is applied and all of the memory cells in the entire block are again verified from the first memory cells of the first sector. Accordingly, the conventional erase verification method for a block erase operation can be very time consuming, particularly for a block with a large number of memory cells. Furthermore, as the flash memory cells degrade over time, the number of erase cycles needed to complete a block erase operation increases. With each erase cycle followed by an erase verify cycle of all of the memory cells, the total erase time for the block erase operation in a flash memory can become longer and longer over time.

In embodiments of the present invention, a non-volatile memory device implements an abridged erase verify method for block erase operation in a flash memory device. The abridged erase verify method stores the address for a memory cell that failed erase verification in each sector. Subsequent erase verification cycle is performed by starting at the stored failed addresses so that previously passed memory cells are not verified again. In this manner, the erase verify time for a block erase operation is significantly reduced. Essentially, the abridged erase verify method achieves an erase verity time that is about the same as the erase verify time required for verifying each memory cell in the block just once, with erase verification repeating only for the failed memory cells. Importantly, the erase verify time for the flash memory device remain the same as the flash memory device ages as the abridged erase verify method only runs through all the memory cells once, regardless of how many erase cycles have been applied. In some embodiments, the abridged erase verify method for block erase operation is implemented in the control circuit of the flash memory device, such as the control circuit 22 of the flash memory device 10 in FIG. 1.

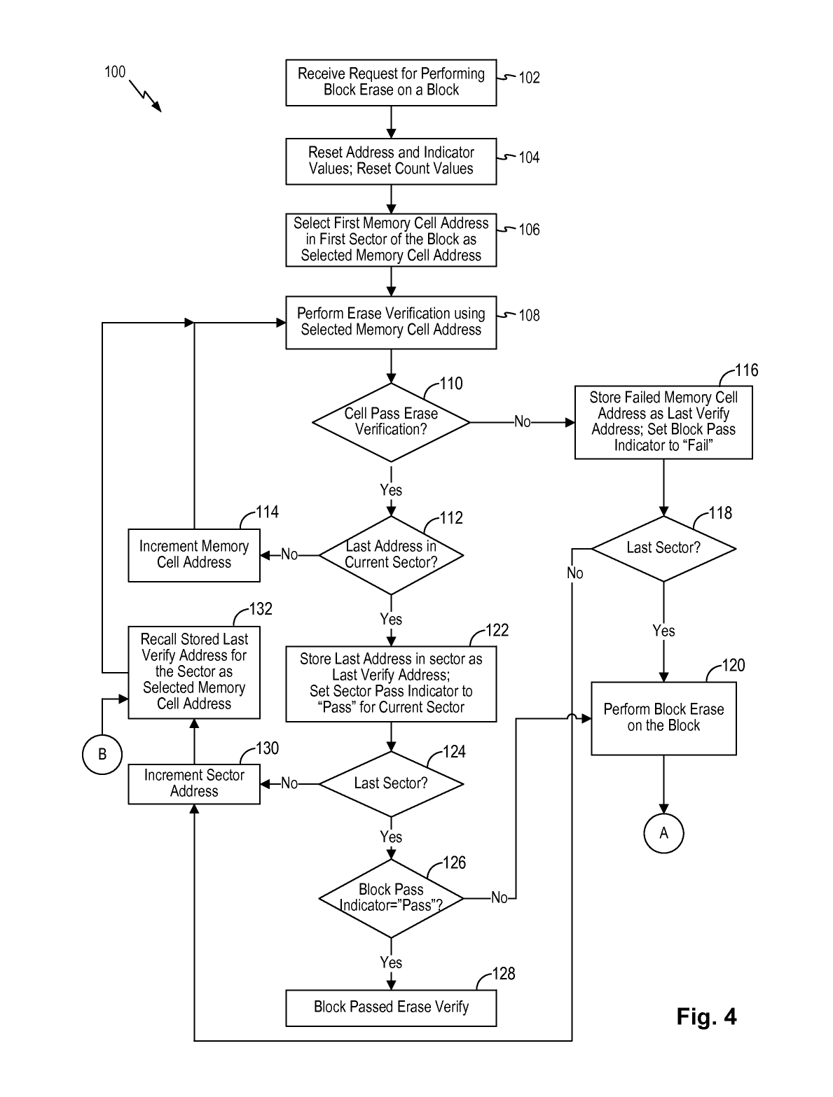

FIG. 4 is a flowchart illustrating an abridged erase verify method for block erase operation in a flash memory device which can be implemented in the flash memory device of FIG. 1 in embodiments of the present invention. Referring to FIG. 4, an abridged erase verify method 100 starts when a request for performing a block erase operation has been received for a given block of memory cells (102). In the present embodiment, an erase verification cycle is performed first prior to any erase cycle. Accordingly, memory cells that are already erased, or are already in the erased state, will not need to be verified again after subsequent erase cycles, as will be explained in more detail below. In other embodiments, a first block erase cycle may be applied before the first erase verification cycle.

Before starting the erase verification cycles, the method 100 resets address and indicator values (104). In the present embodiment, method 100 stores last verify address values for each sector in the block. At the start of the abridged erase verify method, the last verify address values are reset, such as to the first memory cell address in each block. In the present description, the “first memory cell address” may be the least memory cell address value (e.g., 0000h) of the sector, or may be the greatest memory cell address value (e.g., FFFFh) of the sector, or any other memory cell address value in between the least and the greatest address values. The exact memory cell address in the sector used as the “first memory cell address” is not critical to the practice of the present invention. Furthermore, in the present description, the address value is “incremented” by either increasing or decreasing the address value, depending on the starting memory cell address value.

In embodiments of the present invention, the method 100 also stores indicator values. In the present embodiment, the method 100 includes a sector pass indicator and a block pass indicator. The sector pass indicator is used to indicate the verification pass/fail status of a sector. A sector pass verification only if all memory cells in the sector pass erase verification. The block pass indicator is used to indicate the verification pass/fail status of a block. A block pass verification only if all sectors in the block pass erase verification. In the present embodiment, the sector pass indicator is reset to a “fail” state while the block pass indicator is reset to a “pass” state. The indicator reset values are illustrative only and reset values in the opposite polarities may be used in other embodiment. In some embodiments, the method 100 may also reset count values, such as an erase pulse count used to keep track of the number of erase pulses that have been applied.

At 106, the method 100 selects the first memory cell address in the first sector of the block as the selected memory cell address. In the present description, the first sector of the block can be Sector 0 or Sector N−1 or any sector in between for a flash memory device having N sectors. The exact sector being used as the “first sector” is not critical to the practice of the present invention. At 108, the method 100 performs erase verification using the selected memory cell address. At 110, the method 100 determines whether the memory cells passed erase verification. If the memory cell passed erase verification, then method 100 determines if the current address is the last address in the current sector (112). If the current address is not the last address of the sector, then the method 100 increments the memory cell address (114) and the method repeats at 108 where erase verification is performed at the selected memory cell address.

However, at 110, if the memory cell failed erase verification, then method 100 stores the failed memory cell address as the last verify address for that sector (116). The method 100 also set the block pass indicator to a “fail” state as at least one memory cell in one sector has now failed erase verification. A salient feature of the abridged erase verify method of the present invention is that once a failed memory cell is detected in a sector, the erase verify method skips the rest of the memory cells in that sector and move onto the next sector to continue the erase verification process. That is, once a failed memory cell is identified in a sector, the remaining memory cells in the sector are not verified but are skipped at the current erase verify cycle. Accordingly, the method 100 determines if the current sector is the last sector of the block (118). If the current sector is not the last sector, then method 100 proceeds to increment the sector address (130) to continue the erase verification for the next sector. In the present description, incrementing the sector address refers to either increasing or decreasing the sector address value, depending on starting sector address value.

When method 100 moves to the next sector, the method 100 recalls the stored last verify address for the currently selected sector as the selected memory cell address (132). Another salient feature of the abridged erase verify method of the present invention is that each erase verify cycle starts at the last verify address of the current sector so that previously verified pass memory cells in the sector are not verified again. In this manner, repeated verification of passed memory cells is obviated and the erase verify time can be shorted significantly. More specifically, in the first pass of the erase verification method, the sector has not been verified yet and therefore the stored last verify address is the reset address which is the first memory cell in the sector. Thus, the sector is verified from the first memory cell in the first pass. In subsequent passes of the erase verification method, the stored last verify address will be the previous failed memory cell address of that sector, if any, or the last memory cell address of the sector in the case that all memory cells passed. In that case, the sector is verified from the last verify memory cell address or the entire sector is skipped if the sector has passed erase verification. Then the method 100 repeats at 108 where erase verification is performed at the selected memory cell address. In the present description, the “last memory cell address” refers to the memory cell address opposite to the first memory cell address. For example, when the first memory cell address is 0000h, the last memory cell address is FFFFh, and vice versa. When the first memory cell address is 0010h, the last memory cell address will be 0001h.

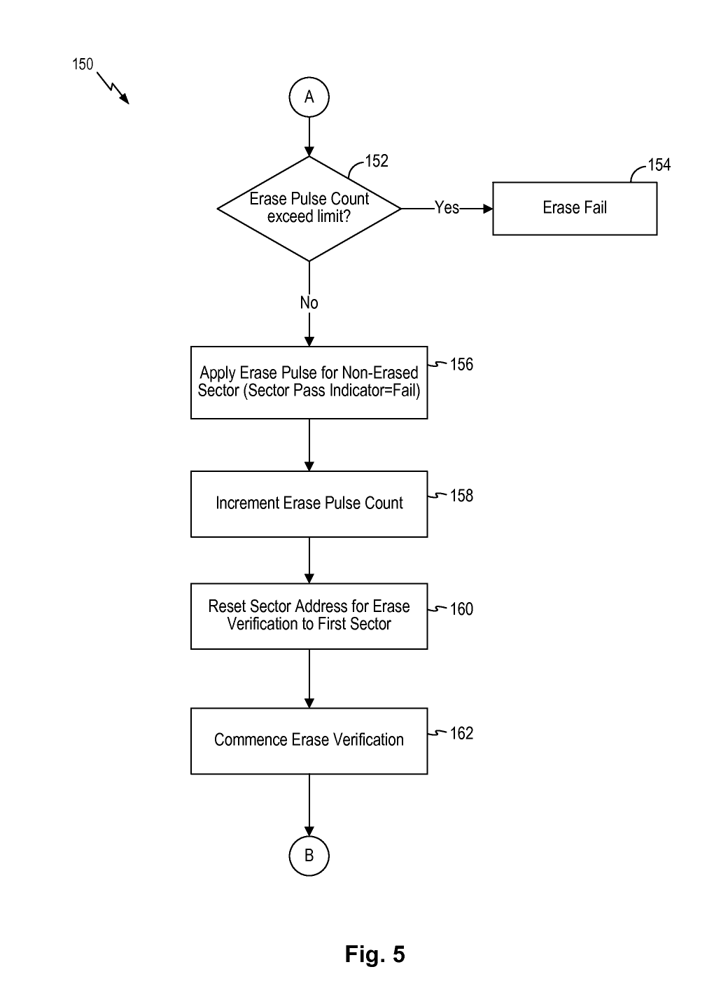

At 118, if the method 100 determines that the current sector is the last sector of the block, then method 100 has completed the current erase verification cycle of the block and at least one memory cell in the block has failed erase verification. Accordingly, method 100 proceeds to perform a block erase cycle on the block (120). In embodiments of the present invention, the block erase cycle is performed using the block erase method of FIG. 5 which will be described in more detail below. The method 100 exits the erase verification cycle at “A” to perform the block erase cycle. When the block erase cycle has completed, erase verification is again performed by returning to method 100 at “B” and where the stored last verify address for the current sector (e.g., the first sector) is recalled and the method 100 repeats at 108 to perform erase verification using the last verify address as the selected memory cell address.

At 112, when a memory cell passes erase verification and the memory cell address is also the last address in the current sector, the method 100 stores the last address of the sector as the last verify address and set the sector pass indicator to “pass” state for the current sector (122). Then, the method 100 determines if the current sector is the last sector of the block (124). If the current sector is not the last sector, then method 100 proceeds to increment the sector address (130) to continue the erase verification for the next sector, in the same manner as described above.

At 124, in the event that the current sector is the last sector of the block (124), the method 100 determines if the block pass indicator has been set to “pass” or “fail” (126). If the block pass indicator has been set to “pass”, then method 100 determines that all sectors in the block has passed erase verification (128) and the block erase operation is completed. If the block pass indicator has been set to “fail”, indicating at least one memory cell in one sector has failed verification, then the method 100 proceeds to perform another block erase cycle on the block (120), in the same manner as described above.

FIG. 5 is a flowchart illustrating a block erase method in a flash memory device in embodiments of the present invention. The block erase method in FIG. 5 can be used in conjunction with the abridged erase verification method of FIG. 4 to perform block erase cycles after one or more memory cells failed erase verification. Referring to FIG. 5, in the present embodiment, the block erase method 150 starts at “A” when a block erase cycle is initiated, such as from 120 in the erase verify method in FIG. 4. The block erase method 150 may also be initiated by other means.

At 152, the method 150 determines if the erase pulse count has exceeded the a predetermined limit. In the present embodiment, the erase pulse count is initiated at the start of the erase verify cycle and each time a block erase cycle is performed, the erase pulse count will be incremented by the block erase method 150. A flash memory device is associated with a maximum erase pulse count value which limits the total number of erase pulses that can be applied to the flash memory device. When the number of erase pulses applied to a flash memory device has reached the predetermined limit, it is determined that the flash memory device has certain malfunction and the block erase operation cannot be completed. Thus, method 150 declares that the block erase operation has failed (154) and terminates the block erase method.

When the erase pulse count is still within the predetermined limit (152), the method 150 proceeds to apply an erase pulse to erase the memory cells in the selected block (156). In embodiments of the present invention, in the block erase cycle, the erase pulse is only applied to non-erased sectors, that is, sectors with a sector pass indicator with a “fail” value. Sectors that have been verified passed and have an associated sector pass indicator with a “pass” value will not be activated during the erase cycle. In this manner, over-erase of the memory cells is prevented. After the erase cycle, the method 150 increments the erase pulse count (158). Then, the method 150 resets the selected sector address for erase verify to the first sector of the block (160) and commences the erase verification cycle (162). In the present embodiment, the abridged erase verify method 100 of FIG. 4 is used and method 150 enters the erase verify method 100 at “B” where the stored last verify address for the current sector is recalled as the selected memory cell address. In this manner, after a block erase cycle, the abridged erase verify method 100 starts at the first sector but at the last failed location in the sector. Previously verified passed memory cells in the sector are not verified again.

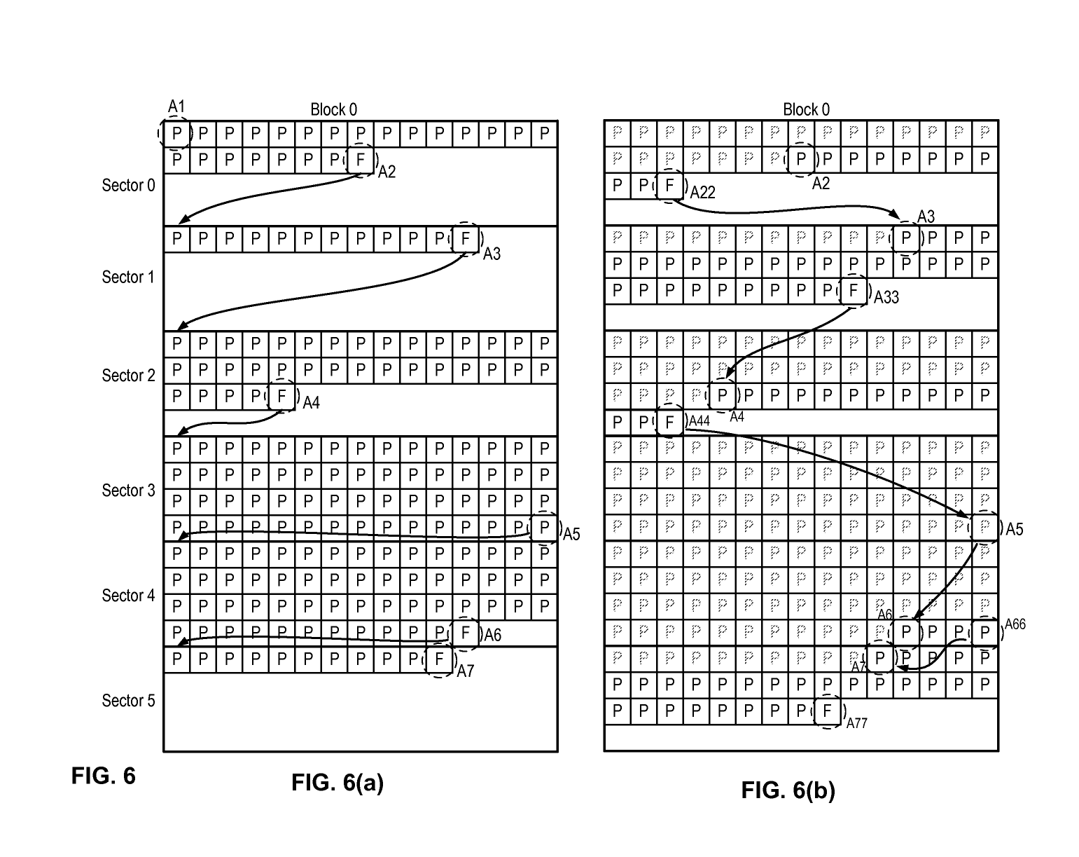

The benefits of the abridged erase verify method of the present invention will become apparent with reference to the example erase verify process shown in FIG. 6. FIG. 6, which includes FIGS. 6(a) and 6(b), illustrates the erase verify process using the abridged erase verify method for block erase operation in some examples of the present invention. FIG. 6(a) illustrates the abridged erase verify method being applied to Block 0 of a flash memory device. When a block erase operation is requested for Block 0, the abridged erase verify method starts an erase verification cycle at the first memory cell address A1 of the first sector (Sector 0) of Block 0. The abridged erase verify method verifies each memory cell until a memory cell at address A2 failed verification. At this point, the abridged erase verify method skips the remaining memory cells in Sector 0 and move onto the next sector (Sector 1). Since this is the first pass through the erase verify cycle, the abridged erase verify method starts at the first memory cell address in Sector 1 and again verifies each memory cell until a failed memory cell (A3) is found. The abridged erase verify method then skips to the next sector (Sector 2) where the erase verification continues to a failed memory cell (A4) in that sector. At the next sector (Sector 3), all memory cells in the sector passed verification. The last address (A5) of Sector 3 is stored and the sector pass indicator is set to “pass”. The abridged erase verify method continues to verify Sectors 4 and 5 with the verification stopping at a failed address in each sector (A6 and A7, respectively).

Following the erase verify cycle in FIG. 6(a), the block has failed erase verification (block pass indicator=“fail”). Thus, a block erase cycle is applied to the block to attempt to erase the memory cells. FIG. 6(b) illustrates the abridged erase verify method being applied after a block erase cycle has been applied to Block 0. Following the block erase cycle, the abridged erase verify method starts the erase verification at the first sector (Sector 0) but from the stored last verify address (A2) of the sector. The last verify address A2 is the first failed address in the sector from the last erase verify cycle. By skipping to the last verify address A2, previously verified memory cells in Sector 0 are not verified again. The erase verification process continues until another failed memory cell is located (A22) in Sector 0. At this point, the abridged erase verify method skips the remaining memory cells in Sector 0 and move to the next sector (Sector 1). Again, the abridged erase verify method starts at the stored last verify address (A3) of Sector 1 and continues until another failed memory cell is located (A33) in Sector 1. The abridged erase verify method continues to Sector 2 in the same manner. The abridged erase verify method skips Sector 3 as the sector passed verification. The abridged erase verify method continues to Sectors 4 and 5 in the same manner. In Sector 4, all memory cells now passed verification and the last address A66 in Sector 4 is stored as the last verify address and the sector pass indicator for Sector 4 is set to “pass”. In Sector 5, the address of the failed memory cell (A77) is stored as the last verify address for the sector. Since the block still has not passed verification, another block erase cycle will be performed and the failed memory cells and the yet unverified memory cells will be verified in the next erase verify cycle.

As can be observed from FIGS. 6(a) and 6(b), the abridged erase verify method scans through the memory cell addresses of the sectors in the block and does not repeat the verification of passed memory cells. After each block erase cycle, the erase verify cycle starts from the last verify address which is the last failed memory cell of each sector. Thus, the erase verify cycle is performed only once for each memory cell passing verification and the erase verify cycle is repeated only for memory cells that failed the erase verification. When the abridged erase verify method of the present invention is applied, significant reduction in erase verify time can be achieved.

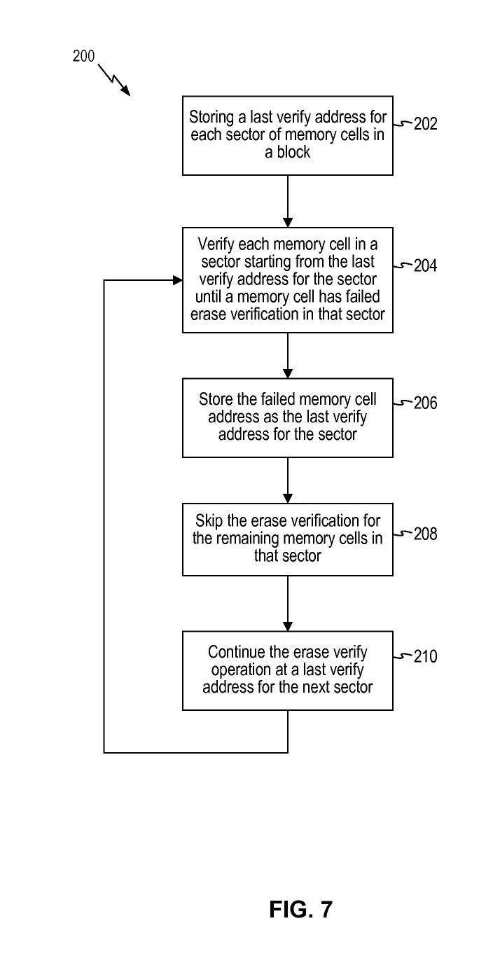

FIG. 7 is a flowchart illustrating an abridged erase verify method in a flash memory device in alternate embodiments of the present invention. Referring to FIG. 7, an abridged erase verify method 200 performs erase verification on a flash memory device including a memory array configured in one or more blocks with each block including two or more sectors. The method 200 starts by storing a last verify address for each sector of memory cells in a block (202). When the abridged erase verify method is started for the first time after a block erase operation has been requested, the first memory cell address is stored as the last verify address. The first memory cell address can be the 0000h or FFFFh or any other memory cells within the sector.

Then, the method 200 verifies each memory cell in a sector starting from the last verify address for the sector until a memory cell has failed erase verification in that sector (204). The method 200 then stores the memory cell address of the failed memory cell as the last verify address for that sector (206). The method 200 then skips the erase verification for the remaining memory cells in that sector (208). The method 200 continues the erase verify cycle at a last verify address for the next sector (210). The method 200 repeats at 204 until all sectors have been verified. When one or more memory cells fail the erase verification, a block erase cycle may be applied and the abridged erased verify method 200 is repeated at 204 after each block erase cycle using the last verify address as the first address in a sector to start erase verification.

In some embodiments, the method 200 may further include, in response to an erase verify cycle being applied to the memory cells for the first time after receiving a request to perform a block erase operation, storing a first memory cell address of each sector as the last verify address for each sector of the block of memory cells.

In some embodiments, the method 200 may further include storing one of a least memory cell address value of the sector, or a greatest memory cell address value of the sector, or any other memory cell address value in between the least and the greatest address values as the first memory cell address.

In some embodiments, the method 200 may further includes, in response to all memory cells in a sector passing erase verification, storing the memory cell address of the last memory cell in the sector as the last verify address for that sector, and setting a sector pass/fail indicator for the sector to a pass state, the sector pass/fail indicator being set to a fail state otherwise.

In some embodiments, the method 200 may further includes, in response to the last sector in the block having been verified and one or more memory cells in the block having failed erase verification, perform a block erase cycle on the block of memory. The block erase cycle is applied to one or more sectors in the block having the sector pass/fail indicator for the sectors set to a fail state and the block erase cycle is not applied to one or more sectors having the sector pass/fail indicator for the sectors set to a pass state.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A non-volatile memory device, comprising:
a two-dimensional array of non-volatile memory cells, the array of memory cells including at least a block of memory cells formed in a first well region, the block of memory cells being divided into two or more sectors of memory cells; and
a control circuit configured to perform a block erase operation on the block of memory cells, the block erase operation including a block erase cycle and an erase verify cycle, the block erase cycle being applied to erase all the memory cells in the block and the erase verify cycle being performed to verify that all the memory cells in the block have been erased,
wherein the control circuit is configured to perform the erase verify cycle by storing a last verify address for each sector of the block of memory cells, verifying each memory cell in a sector starting from the last verify address for the sector until a memory cell has failed erase verification in that sector, storing the memory cell address of the failed memory cell as the last verify address for that sector, skipping the erase verification for the remaining memory cells in that sector, and continuing the erase verify cycle at a last verify address for the next sector.

2. The non-volatile memory device of claim 1, wherein the last verify address for each sector of the block of memory cells comprises a first memory cell address of each sector for an erase verify cycle being applied to the memory cells for the first time after receiving a request to perform a block erase operation.

3. The non-volatile memory device of claim 2, wherein the first memory cell address of a sector comprises one of a least memory cell address value of the sector, or a greatest memory cell address value of the sector, or any other memory cell address value in between the least and the greatest address values.

4. The non-volatile memory device of claim 1, wherein the control circuit is configured to perform the erase verify cycle by storing the memory cell address of the last memory cell in a sector as the last verify address for that sector in response to all memory cells in that sector passing erase verification, the control circuit being further configured to set a sector pass/fail indicator for the sector to a pass state, the sector pass/fail indicator being set to a fail state otherwise.

5. The non-volatile memory device of claim 4, wherein the control circuit is further configured to perform a block erase cycle on the block of memory in response to the last sector in the block having been verified and one or more memory cells in the block having failed erase verification, the block erase cycle being applied to one or more sectors in the block having the sector pass/fail indicator for the sectors set to a fail state and the block erase cycle not being applied to one or more sectors having the sector pass/fail indicator for the sectors set to a pass state.

6. A method of performing erase verify operation on a non-volatile memory device in response to receiving a request for a block erase operation, the block erase operation including a block erase cycle and an erase verify cycle, the block erase cycle being applied to erase all the is memory cells in the block and the erase verify cycle being performed to verify that all the memory cells in the block have been erased, the non-volatile memory device comprising a two-dimensional array of non-volatile memory cells, the array of memory cells including at least one block of memory cells formed in a first well region, each block of memory cells being divided into two or more sectors of memory cells, the method comprising:
storing a last verify address for each sector of the block of memory cells;
performing the erase verify cycle on each memory cell in a sector starting from the last verify address for the sector until a memory cell has failed erase verification in that sector;
in response to detecting a memory cell in the sector having failed erase verification, storing the memory cell address of the failed memory cell as the last verify address for that sector and skipping erase verification of the remaining memory cells in that sector; and
continuing the erase verify cycle at a last verify address for the next sector.

7. The method of claim 6, further comprising:
in response to an erase verify cycle being applied to the memory cells for the first time after receiving a request to perform a block erase operation, storing a first memory cell address of each sector as the last verify address for each sector of the block of memory cells.

8. The method of claim 7, wherein storing a first memory cell address of each sector as the last verify address comprises:
storing one of a least memory cell address value of the sector, or a greatest memory cell address value of the sector, or any other memory cell address value in between the least and the greatest address values as the first memory cell address.

9. The method of claim 6, further comprising:
in response to all memory cells in a sector passing erase verification, storing the memory cell address of the last memory cell in the sector as the last verify address for that sector; and
setting a sector pass/fail indicator for the sector to a pass state, the sector pass/fail indicator being set to a fail state otherwise.

10. The method of claim 9, further comprising:
in response to the last sector in the block having been verified and one or more memory cells in the block having failed erase verification, perform the block erase cycle on the block of memory, the block erase cycle being applied to one or more sectors in the block having the sector pass/fail indicator for the sectors set to a fail state and the block erase operation not being applied to one or more sectors having the sector pass/fail indicator for the sectors set to a pass state.
